(19) United States
(12) Patent Application Publication
(10) Pub. No.: US 2025/0183847 A1
(43) Pub. Date: Jun. 5, 2025

(54) DOHERTY AMPLIFIER CIRCUIT

(71) Applicant: SUMITOMO ELECTRIC DEVICE INNOVATIONS, INC., Yokohama-shi (JP)

(72) Inventor: Takashi SUMIYOSHI, Yokohama-shi (JP)

(73) Assignee: SUMITOMO ELECTRIC DEVICE INNOVATIONS, INC., Yokohama-shi (JP)

(21) Appl. No.: 18/911,791

(22) Filed: Oct. 10, 2024

(30) Foreign Application Priority Data
Nov. 30, 2023 (JP) 2023-203143

(51) Int. Cl. H03F 1/02; H03F 3/21; H03F 3/213

(52) U.S. Cl. CPC H03F 1/0288; H03F 3/211; H03F 3/213; H03F 2200/222; H03F 2200/387; H03F 2203/21142

(57) ABSTRACT

Doherty amplifier circuit includes a divider configured to divide an input signal into a first signal to a third signal and makes power of the second signal larger than that of the third signal, a main amplifier configured to amplify the first signal and output the amplified signal as a fourth signal, a first peak amplifier configured to amplify the second signal and output the amplified signal as a fifth signal, a second peak amplifier configured to amplify the third signal and output the amplified signal as a sixth signal, and a combiner configured to combine the fourth signal, the fifth signal and the sixth signal and output the combined signal as an output signal to an output terminal. An input power of the input signal for turning on the first peak amplifier is smaller than the input power for turning on the second peak amplifier.

### CROSS REFERENCE TO RELATED APPLICATIONS

This application claims priority based on Japanese Patent Application No. 2023-203143 filed on Nov. 30, 2023, and the entire contents of the Japanese patent applications are incorporated herein by reference.

### FIELD OF THE INVENTION

A certain aspect of the embodiments is related to a Doherty amplifier circuit.

### BACKGROUND ART

There is known an N (>3)-way Doherty amplifier circuit using a main amplifier and two or more of peak amplifiers (for example, see U.S. Pat. Nos. 8,022,760 and 10,601,375).

### SUMMARY OF THE INVENTION

A Doherty amplifier circuit includes: a divider configured to divide an input signal into a first signal, a second signal and a third signal and makes power of the second signal larger than that of the third signal; a main amplifier configured to amplify the first signal and output the first signal after amplifying as a fourth signal; a first peak amplifier configured to amplify the second signal and output the second signal after amplifying as a fifth signal; a second peak amplifier configured to amplify the third signal and output the third signal after amplifying as a sixth signal; and a combiner configured to combine the fourth signal, the fifth signal and the sixth signal and output a combined signal of the fourth signal, the fifth signal and the sixth signal as an output signal to an output terminal, wherein an input power of the input signal for turning on the first peak amplifier is smaller than the input power for turning on the second peak amplifier.

### BRIEF DESCRIPTION OF THE DRAWINGS

FIG. 1 is a block diagram of a Doherty amplifier circuit according to a first embodiment.

FIG. 2 is a plan view of a semiconductor device in a first embodiment.

FIG. 3 is a schematic diagram illustrating a probability for Pout, Pout of each amplifier with respect to Pin, a gain of each amplifier with respect to Pin, and an overall gain with respect to Pin in a first embodiment and Comparative Example 1.

FIG. 4 is a Smith chart illustrating a load impedance in a first embodiment.

FIG. 5 is a Smith chart illustrating a load impedance in Modified Example 1 of a first embodiment.

FIG. 6 is a plan view of a semiconductor device in a second embodiment.

FIG. 7 is a schematic diagram showing a probability for Pout, Pout of each amplifier with respect to Pin, a gain of each amplifier with respect to Pin, and an overall gain with respect to Pin in a second embodiment and a first embodiment.

### DETAILED DESCRIPTION

In a Doherty amplifier circuit, it is required to improve a gain of a modulated wave to be amplified.

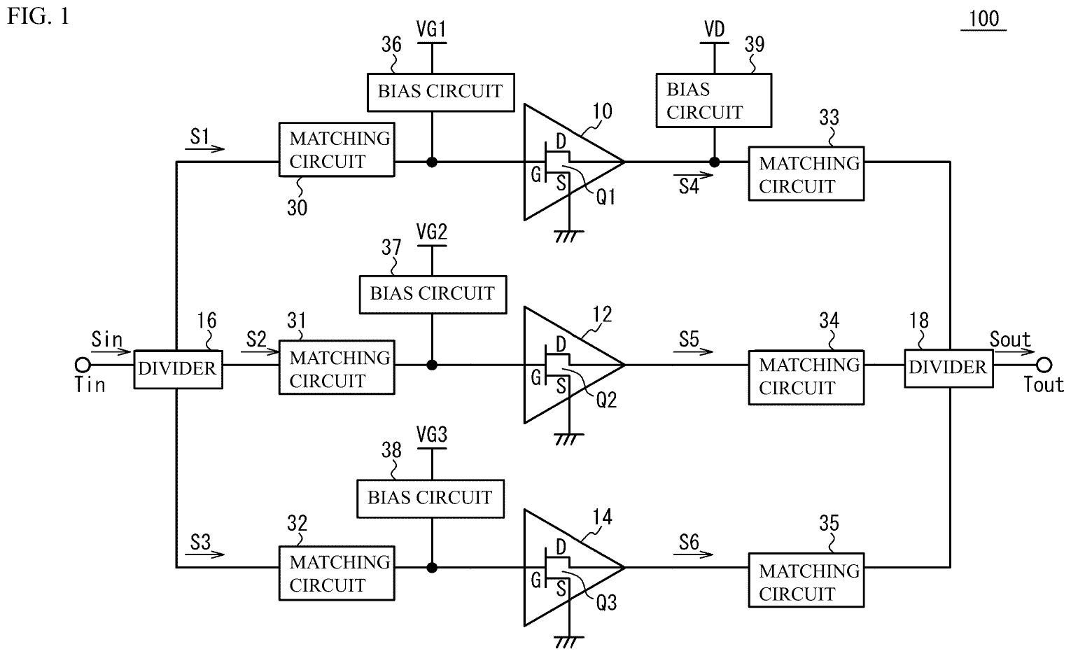

As an example of a Doherty amplifier circuit, a high-output high-frequency amplifier circuit used in a mobile communication base station will be described. In this case, the frequency of the high-frequency signal is, for example, 0.5 GHz or more and 10 GHz or less. FIG. 1 is a block diagram of a Doherty amplifier circuit according to a first embodiment.

As illustrated in FIG. 1, in a Doherty amplifier circuit 100, a main amplifier 10, a peak amplifier 12 (first peak amplifier), and a peak amplifier 14 (second peak amplifier) are connected in parallel between a divider 16 and a combiner 18. In this way, the Doherty amplifier circuit 100 is a 3-way amplifier circuit. The Doherty amplifier circuit may be an N-way Doherty amplifier circuit having three or more peak amplifiers.

A high-frequency signal is input to an input terminal Tin as an input signal Sin. The divider 16 divides the input signal Sin input to the input terminal Tin into signals S1 (first signal), S2 (second signal), and S3 (third signal). The divider 16 is, for example, a Wilkinson type divider.

The path to which the signal S1 is input includes a matching circuit 30, a bias circuit 36, the main amplifier 10, a bias circuit 39, and a matching circuit 33. The path to which the signal S2 is input includes a matching circuit 31, a bias circuit 37, the peak amplifier 12, and a matching circuit 34. The path to which the signal S3 is input includes a matching circuit 32, a bias circuit 38, the peak amplifier 14, and a matching circuit 35.

The matching circuits 30 to 32 match the impedances in a case of seeing the matching circuits 30 to 32 respectively from the divider 16 with the impedances in a case of seeing the main amplifier 10 and the peak amplifiers 12 and 14 respectively from the matching circuits 30 to 32. The bias circuits 36 to 38 supply gate bias voltages VG1 to VG3 to the gates G of the main amplifier 10 and the peak amplifiers 12 and 14, respectively, and suppress leakage of the signals S1 to S3 to the bias terminals.

The main amplifier 10, the peak amplifiers 12 and 14 amplify the signals S1, S2 and S3, respectively, and output the amplified signals S4 (fourth signal), S5 (fifth signal) and S6 (sixth signal), respectively. The bias circuit 39 supplies a drain bias voltage VD to the drains D of the main amplifier 10 and suppresses the signal S4 from leaking to the bias terminal. The matching circuits 33 to 35 match the impedances in a case of seeing the matching circuits 33 to 35 respectively from the peak amplifiers 12 and 14 with the impedances in a case of seeing the combiner 18 respectively from the matching circuits 33 to 35. The combiner 18 combines the signals S4 to S6, and outputs the combined signal as the output signal Sout to the output terminal Tout.

The main amplifier 10, the peak amplifiers 12 and 14 each include transistors Q1 to Q3. The transistors Q1 to Q3 are, for example, FETs (Field Effect Transistors), such as GaN HEMTs (Gallium Nitride High Electron Mobility Transistors) or LDMOSs (Laterally Diffused Metal Oxide Semiconductors). The sources S of the transistors Q1 to Q3 are grounded, the signals S1 to S3 are input to the gates G, and the signals S4 to S6 are output from the drains D.

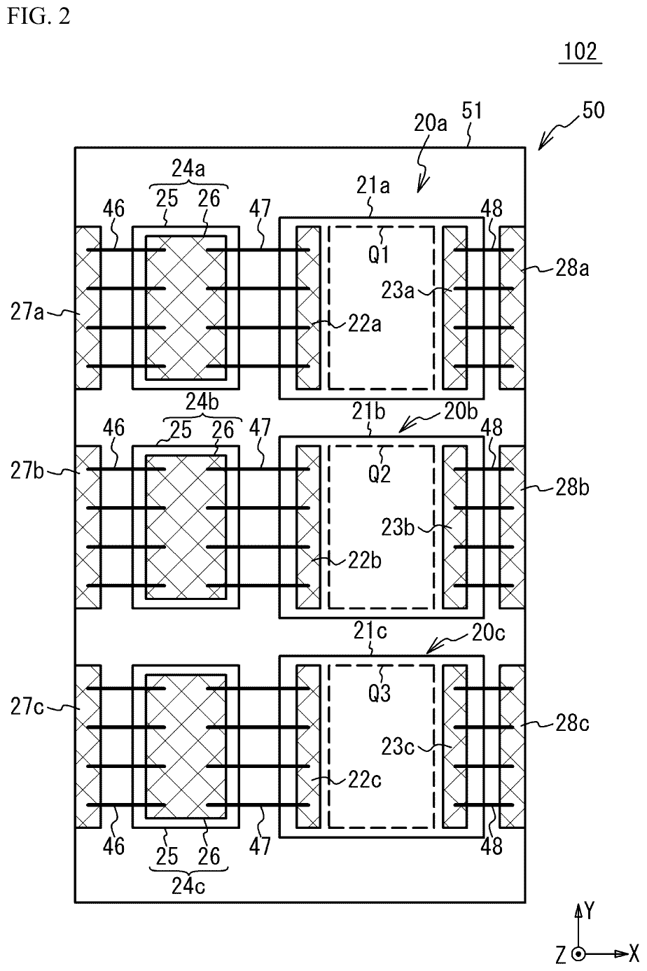

FIG. 2 is a plan view of a semiconductor device of the first embodiment. The lid of a package 50 is not illustrated in FIG. 2. The thickness direction of a base 51 of the package 50 is the Z direction, the direction from leads 27a to 27c to leads 28a to 28c is the X direction (second direction intersecting the first direction), and the direction perpendicular to the X and Z directions is the Y direction (first direction).

As illustrated in FIG. 2, in a semiconductor device 102, the package 50 has the base 51 whose upper surface is conductive at least. The base 51 is a conductive substrate such as a laminated substrate of copper and molybdenum. A reference potential such as a ground potential is supplied to the base 51. Semiconductor chips 20a to 20c and capacitive components 24a to 24c are mounted on the base 51.

The leads 27a to 27c are provided on the negative side of the base 51 in the X direction, sandwiching an insulating layer (not illustrated). The leads 28a to 28c are provided on the positive side of the base 51 in the X direction, sandwiching an insulating layer (not illustrated). The leads 27a to 27c and 28a to 28c are, for example, metal layers or metal plates made of copper or the like. The signals S1 to S3 are input to the leads 27a to 27c, respectively, and the signals S4 to S6 are output from the leads 28a to 28c, respectively.

The semiconductor chip 20a includes a substrate 21a, the transistor Q1, pads 22a and 23a provided on the upper surface of the substrate 21a, and an electrode (not illustrated) provided on the lower surface of the substrate 21a. The pads 22a and 23a and the lower electrode are electrically connected to the gate G, the drain D and the source S of the transistor Q1, respectively. The semiconductor chip 20b includes a substrate 21b, the transistor Q2, pads 22b and 23b provided on the upper surface of the substrate 21b, and an electrode provided on the lower surface of the substrate 21b. The pads 22b and 23b and the lower electrode are electrically connected to the gate G, the drain D and the source S of the transistor Q2, respectively. The semiconductor chip 20c includes a substrate 21c, the transistor Q3, pads 22c and 23c provided on the upper surface of the substrate 21c, and an electrode provided on the lower surface of the substrate 21c. The pads 22c and 23c and the bottom electrode are electrically connected to the gate G, the drain D and the source S of the transistor Q3, respectively.

The substrates 21a to 21c are semiconductor substrates. If the transistors Q1 to Q3 are GaN HEMTs, the substrates 21a to 21c are, for example, silicon carbide (SiC) substrates, sapphire substrates or gallium nitride (GaN) substrates. If the transistors Q1 to Q3 are LDMOS, the substrates 21a to 21c are, for example, silicon (Si) substrates. The pads 22a to 22c, 23a to 23c and the bottom electrode are, for example, metal layers such as gold layers. The transistors Q1 to Q3 are the same size (for example, the gate width is the same, and the saturation electrical power when the gate bias voltage and drain bias voltage are the same).

The capacitive components 24a to 24c each include a dielectric substrate 25, an electrode 26 provided on the upper surface of the dielectric substrate 25, and an electrode provided on the lower surface of the dielectric substrate 25. The electrode 26 and the electrode on the lower surface sandwiching the dielectric substrate 25 form a capacitor. The dielectric substrate 25 is, for example, an alumina substrate or a barium titanate substrate. The electrode 26 is, for example, a metal layer such as a gold layer.

Bonding wires 46 electrically connect the leads 27a to 27c and the electrodes 26 of the capacitive components 24a to 24c, respectively. Bonding wires 47 electrically connect the electrodes 26 of the capacitive components 24a to 24c and the pads 22a to 22c, respectively. Bonding wires 48 electrically connect the pads 23a to 23c and the leads 28a to 28c, respectively. The bonding wires 46 to 48 are, for example, metal wires such as gold wires or aluminum wires.

The bonding wires 46 and 47 function as inductors, and the capacitive components 24a to 24c function as capacitors. The bonding wires 46 and 47 and the capacitive components 24a to 24c correspond to the matching circuits 30 to 32 of the T-type LCL circuit.

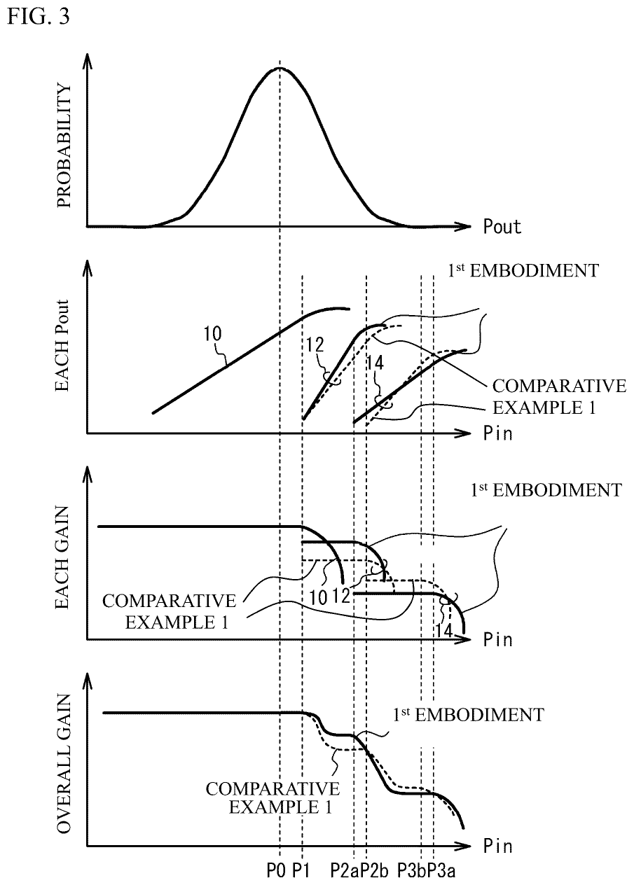

FIG. 3 is a schematic diagram illustrating the probability for Pout, Pout of each amplifier for Pin, the gain of each amplifier for Pin, and the overall gain for Pin in the first embodiment and Comparative Example 1.

The probability is the probability of a modulated wave signal of a high-frequency signal for mobile communications amplified by the Doherty amplifier circuit 100. In other words, the probability is the probability that the Doherty amplifier circuit 100 outputs a certain output power Pout. Each Pout is the output power Pout of the main amplifier 10 and the peak amplifiers 12 and 14. Each gain is the power gain of each of the main amplifier 10 and the peak amplifiers 12 and 14. The overall gain is the power gain of the output power Pout of the output signal Sout relative to the input power Pin of the input signal Sin. Note that Pin and Pout are expressed in dB. The gain of the main amplifier 10 at or below the power P1 is greater than the gain of the peak amplifier 12 at or above the power P1 and at or below the power P2. That is, the slope of Pout with respect to the input power Pin of the main amplifier 10 at power P1 or less is larger than the slope of Pout with respect to the input power Pin of the peak amplifier 12 at power P1 or more and P2 or less. However, FIG. 3 is a schematic diagram, and the slope of Pout with respect to the input power Pin of the main amplifier 10 at power P1 or less is smaller than the slope of Pout with respect to the input power Pin of the peak amplifier 12 at power P1 or more and P2 or less. The dashed line shows Comparative Example 1, and the solid line shows the first embodiment.

[Explanation of Comparative Example 1] In Comparative Example 1, the distribution ratio of the divider 16 is the same for the signals S2 and S3. As illustrated in FIG. 3, in Comparative Example 1, when the output power Pout is power P0, the probability of a modulated wave is the highest. In other words, when a modulated wave signal is output, the time when the output power Pout is power P0 is the longest. The main amplifier 10 is a class A or class AB amplifier, and the peak amplifiers 12 and 14 are class C amplifiers. The input power Pin at which the peak amplifier 12 turns on is greater than the input power Pin at which the main amplifier 10 turns on, and the input power Pin at which the peak amplifier 14 turns on is greater than the input power Pin at which the peak amplifier 12 turns on. To operate in this manner, the gate bias voltage VG2 of the transistor Q2 is made more negative than the gate bias voltage VG1 of the transistor Q1, and the gate bias voltage VG3 of the transistor Q3 is made more negative than the gate bias voltage VG2 of the transistor Q2.

When the input power Pin of the input signal Sin increases and the input power Pin exceeds the power P0 up to the power P1, the main amplifier 10 operates, but the peak amplifiers 12 and 14 do not operate. When the input power Pin is equal to or less than the power P1, as the input power Pin increases, the output power Pout of the main amplifier 10 increases linearly. For this reason, when the input power Pin is equal to or less than the power P1, each gain and the overall gain are almost constant.

When the input power Pin is equal to or more than the power P1 and equal to or less than the power P2b, the main amplifier 10 and the peak amplifier 12 operate, but the peak amplifier 14 does not operate. In this range, the main amplifier 10 saturates. For this reason, the gain of the main amplifier 10 decreases. Accordingly, the overall gain also decreases. Since the peak amplifier 12 operates in class C, the gain of the peak amplifier 12 between the power P1 and P2b is lower than the gain of the main amplifier 10 at or below the power P1. In addition, the saturation power of the peak amplifier 12 is smaller than the saturation power of the main amplifier 10.

When the input power Pin is equal to or greater than the power P2b and equal to or less than the power P3b, the main amplifier 10, the peak amplifier 12 and 14 all operate. In this range, the peak amplifier 12 as well as the main amplifier 10 saturates. Therefore, the gain of the peak amplifier 12 decreases. Accordingly, the overall gain also decreases. Since the operating point of the peak amplifier 14 is more negatively larger than the operating point of the peak amplifier 12, the gain of the peak amplifier 14 between the powers P2b and P3b is lower than the gain of the peak amplifier 12 between the powers P1 and P2b. In addition, the saturation power of the peak amplifier 14 is lower than the saturation power of the peak amplifier 12.

When the input power Pin is equal to or greater than the power P3b, the peak amplifier 14 as well as the main amplifier 10 and the peak amplifier 12 saturates. Therefore, the gain of the peak amplifier 14 decreases. Accordingly, the overall gain also decreases.

The product of the probability and the overall gain corresponds to the gain of the modulated wave. In order to improve the gain of the modulated wave, the overall gain at Pout with high probability is improved.

[Explanation of the first embodiment] In the first embodiment, the power of the signal S2 is distributed more than the power of the signal S3. That is, if the amplitude of the power of the signal S2 is A2 (shown in W) and the amplitude of the power of the signal S3 is A3 (shown in W), then A2>A3. For example, A2:A3=2:1 is set.

As illustrated in FIG. 3, when the input power Pin is P1 or less, each Pout, each gain, and the overall gain are the same as those of Comparative Example 1. When the input power Pin is P1 or more, the peak amplifier 12 operates in addition to the main amplifier 10. Since the distribution ratio A2/A3 of the signal S2 of the divider 16 is greater than 1, the Pout of the peak amplifier 12 rises more rapidly than that of Comparative Example 1. The gain of the input signal Sin of the peak amplifier 12 with respect to the input power Pin is greater than that of Comparative Example 1. Therefore, the overall gain is greater than that of Comparative Example 1. The peak amplifier 12 is saturated when the input power Pin reaches the power P2a, which is smaller than the power P2b of Comparative Example 1.

When the input power Pin becomes equal to or greater than the power P2a, the main amplifier 10 and the peak amplifiers 12 and 14 all operate. The peak amplifier 12 becomes saturated and its gain decreases, so the overall gain also decreases. Since the distribution ratio A3/A2 of the signal S3 of the divider 16 is smaller than 1, the Pout of the peak amplifier 14 rises more slowly than in Comparative Example 1. The gain of the input signal Sin of the peak amplifier 14 with respect to the input power Pin becomes smaller than in Comparative Example 1. Therefore, the overall gain becomes smaller than in Comparative Example 1. The peak amplifier 14 becomes saturated when the input power Pin is equal to the power P3a. The power P3a is greater than the power P3b in Comparative Example 1.

As described above, in the first embodiment, compared to Comparative Example 1, the overall gain is greater when the input power Pin is between the power P1 and P2a (or P2b), and the overall gain is smaller when the input power Pin is equal to or greater than the power P2a (or P2b).

The gain of the modulated wave is the product of the probability of the modulated wave and the overall gain. In the first embodiment, the divider 16 distributes the power of the signal S2 more than the power of the signal S3. As a result, in the range of the powers P1 to P2a with high probability, the overall gain is greater than in Comparative Example 1. Therefore, the gain of the modulated wave can be improved compared to Comparative Example 1, and the characteristics are improved.

From the viewpoint of improving the gain of the modulated wave, the ratio A2/A3 of the amplitude A2 of the power of the signal S2 to the amplitude A3 of the power of the signal S3 may be 1.2 or more, 1.5 or more, or 2 or more. If the amplitude A3 of the signal S3 is too small, the gain will decrease when the input power Pin is large. From this viewpoint, the ratio A2/A3 may be 10 or less, or 5 or less.

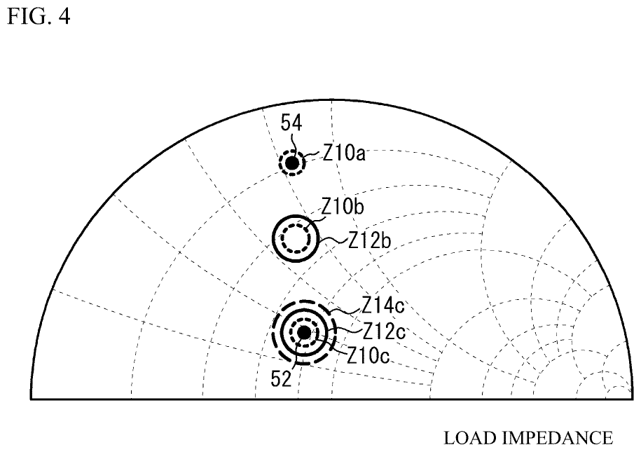

FIG. 4 is a Smith chart showing the load impedance in the first embodiment. The upper half of the Smith chart is illustrated. The load impedances are imaginary values for explaining the load impedance of each amplifier. The load impedances Z10, Z12 and Z14 of the main amplifier 10 and the peak amplifiers 12 and 14 are the impedances in a case of seeing the matching circuits 33 to 35 (that is, the combiner 18) respectively from the main amplifier 10 and the peak amplifiers 12 and 14 in FIG. 1.

In FIG. 4, a gain matching impedance 52 is the impedance at which the gain (power gain) is maximized at the center frequency of the operating band when the main amplifier 10 and the peak amplifiers 12 and 14 are load-pull measured. An efficiency matching impedance 54 is the impedance at which the drain efficiency is maximized at the center frequency of the operating band when the main amplifier 10 and the peak amplifiers 12 and 14 are load-pull measured.

In FIG. 4, the gain matching impedances 52 of the main amplifier 10 and the peak amplifiers 12 and 14 are the same, but they may be different from each other. The efficiency matching impedances 54 of the main amplifier 10 and the peak amplifiers 12 and 14 are the same, but they may be different from each other.

The load impedances Z10a, Z10b and Z10c are the load impedances at the center frequency of the operating band when the input power Pin of the main amplifier 10 is the power P1, P2, and P3, respectively. The load impedances Z12b and Z12c are the load impedances at the center frequency of the operating band when the input power Pin of the peak amplifier 12 is the power P2 and P3, respectively. The load impedance Z14c is the load impedance at the center frequency of the operating band when the input power Pin of the peak amplifier 14 is the power P3.

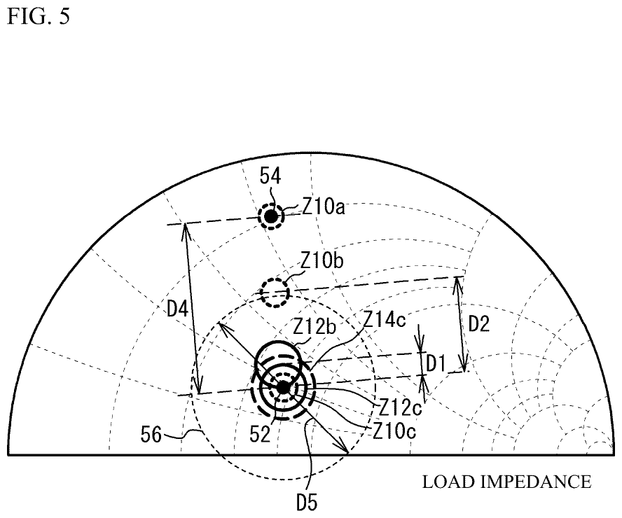

When the input power Pin is the power P1, the load impedance Z10a is near the efficiency matching impedance 54. When the input power Pin is the power P2, the load impedances Z10b and Z12b are located between the efficiency matching impedance 54 and the gain matching impedance 52. When the input power Pin is the power P3, the load impedances Z10c, Z12c and Z14c are located near the gain matching load impedance 52. This allows the efficiency of the Doherty amplifier circuit 100 to be increased at the power P1. At the power P2, the efficiency and the gain of the Doherty amplifier circuit 100 may be moderate. At the power P3, the gain of the Doherty amplifier circuit 100 may be increased.

[Modified Example 1 of the first embodiment] FIG. 5 is a Smith chart showing the load impedance in Modified Example 1 of the first embodiment. As illustrated in FIG. 5, in Modified Example 1 of the first embodiment, the load impedance Z12b when the input power Pin of the peak amplifier 12 is the power P2 is closer to the gain matching impedance 52 than in the first embodiment. The rest of the configuration is the same as in the first embodiment, so a description will be omitted.

In Modified Example 1 of the first embodiment, when the input power Pin is the power P2 (that is, when the main amplifier 10 and the peak amplifier 12 are operating and the peak amplifier 14 is not operating), a first distance D1 is the distance between a first position on the Smith chart of the load impedance Z12b and a second position on the Smith chart of the gain matching impedance 52. A second distance D2 is the distance between the position on the Smith chart of the load impedance Z10b and the position on the Smith chart of the gain matching impedance 52. At this time, the distance D1 is shorter than the distance D2. This improves the gain of the peak amplifier 12 at the power P2, and improves the overall gain at the power P2a in FIG. 3. Therefore, the gain of the modulated wave can be improved, and the characteristics are further improved.

From the viewpoint of improving the gain of the peak amplifier 12 at the power P2, the distance D1 may be set to 0.8 times or less, 0.6 times or less, or 0.4 times or less of the distance D2.

At the power P2, the distance between the position on the Smith chart of the impedance 52 of the gain matching of the peak amplifier 12 and a third position on the Smith chart of the impedance 54 of the efficiency matching of the peak amplifier 12 is D4. On the Smith chart, a circle 56 is drawn with the impedance 52 at its center and a diameter D5 at the distance D4. At this time, the load impedance Z12b is located inside the circle 56. This allows the gain of the peak amplifier 12 to be improved at the power P2, and the characteristics are further improved.

From the viewpoint of improving the gain of the peak amplifier 12 at the power P2, the diameter D5 of the circle 56 may be set to 0.8 times or less, 0.6 times or less, or 0.4 times or less of the distance D4.

When the input power Pin is the power P3 (that is, when the main amplifier 10 and the peak amplifiers 12 and 14 are operating), the third distance D3 (almost 0 in FIG. 5) is the distance between a fourth position on the Smith chart of the load impedance Z12c of the peak amplifier 12 and the second position on the Smith chart of the gain matching impedance 52. At this time, the third distance D3 is equal to or less than the first distance D1. This allows the gain of the peak amplifier 12 to be improved at the powers P2 and P3, further improving the characteristics.

From the viewpoint of improving the gain of the peak amplifier 12 at the power P3, the third distance D3 may be set to 0.8 times or less, 0.6 times or less, or 0.4 times or less of the first distance D1.

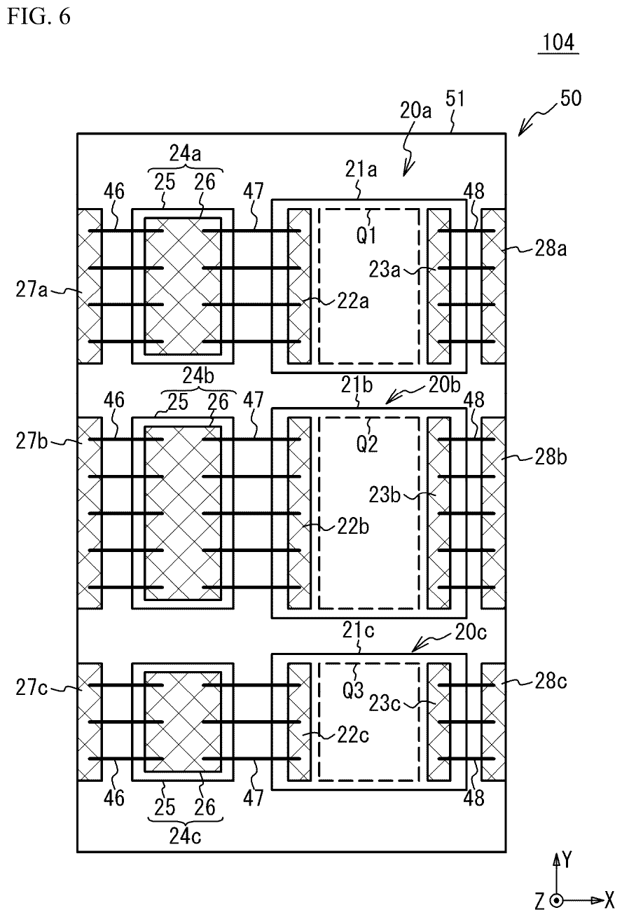

As in the first embodiment and its Modified Example 1, when the same bias voltage (gate bias voltage and drain bias voltage) is supplied to the peak amplifier 12 and the peak amplifier 14, the saturation power of the peak amplifier 12 and the saturation power of the peak amplifier 14 may be equal. This allows the peak amplifiers 12 and 14 to use amplifiers with the same structure (that is, semiconductor chips). Note that the saturation power of the peak amplifier 12 and the saturation power of the peak amplifier 14 being equal (or approximately equal) allows for a difference of the order of manufacturing error. For example, the difference between the saturation power of the peak amplifier 12 and the saturation power of the peak amplifier 14 may be set to 1 dBm or less, or 0.5 dBm or less. The saturation power does not have to be the power at which the output power is completely saturated. The saturation power may be, for example, 1 dBm to 3 dBm lower than the power at which the output power is completely saturated. When comparing the saturation power of different amplifiers, the comparison may be performed using a power that is a certain value lower than the power at which the output power is completely saturated.

[Second Embodiment] FIG. 6 is a plan view of a semiconductor device in a second embodiment. As illustrated in FIG. 6, in a semiconductor device 104 of the second embodiment, the transistor Q2 is larger than the transistor Q3. That is, the transistor Q2 is larger than the transistor Q3 (for example, the gate width is larger, and the saturation power is larger when the gate bias voltage and drain bias voltage are the same).

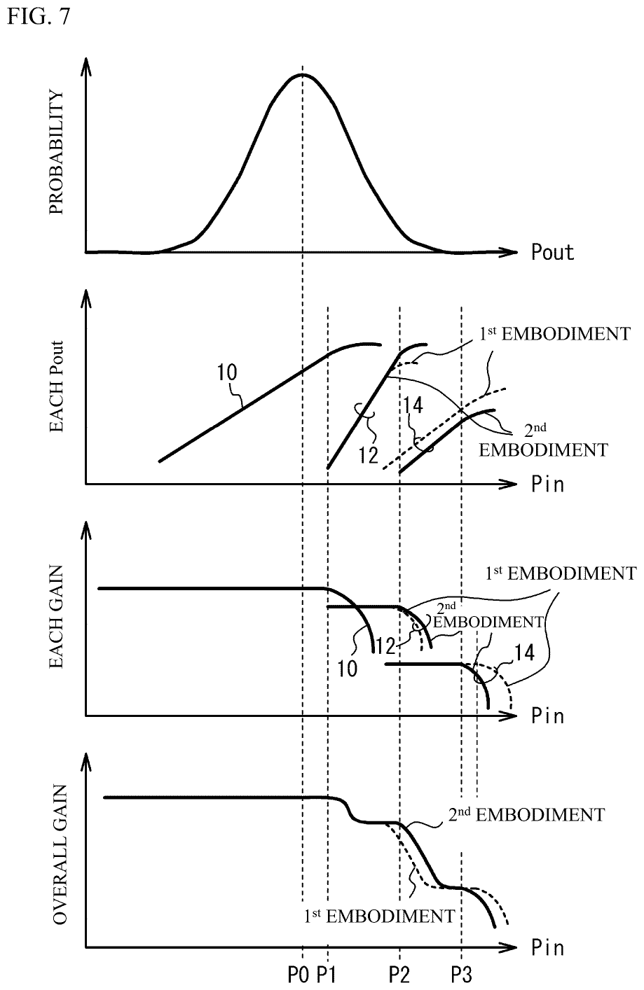

FIG. 7 is a schematic diagram illustrating the probability for Pout, the Pout of each amplifier for Pin, the gain of each amplifier for Pin, and the overall gain for Pin in the second embodiment and the first embodiment. The dashed line shows the first embodiment, and the solid line shows the second embodiment.

When the same gate bias voltage and drain bias voltage are supplied to the transistors Q2 and Q3, the saturation powers of the transistors Q2 and Q3 are Ps2 and Ps3 (indicated in W), respectively. At this time, the ratio Ps2/Ps3 of Ps2 (indicated in W) to Ps3 is approximately equal to the ratio A2/A3. At this time, when the input power Pin becomes larger than the power P1, the gain of the peak amplifier 12 is approximately the same in the second embodiment and the first embodiment. The peak amplifier 12 in the first embodiment saturates at a power smaller than the power P2 (power P2a in FIG. 3), whereas the peak amplifier 12 in the second embodiment does not saturate until the power P2 (power P2b in FIG. 3). Therefore, the gain of the peak amplifier 12 does not decrease until the power P2. The overall gain of the second embodiment does not decrease until the input power Pin, which is larger than that of the first embodiment, is near the power P2.

When the input power Pin becomes greater than the power P2, the gain of the peak amplifier 14 is almost the same in the second embodiment and the first embodiment. The peak amplifier 14 in the first embodiment saturates at a power greater than the power P3, whereas the peak amplifier 14 in the second embodiment saturates at the power P3. Therefore, the gain of the peak amplifier 14 decreases at the power P3 smaller than that in the first embodiment. The overall gain of the second embodiment is smaller than that of the first embodiment near the power P3.

In the second embodiment, when the same bias voltage (gate bias voltage and drain bias voltage) is supplied to the peak amplifier 12 and the peak amplifier 14, the saturation power of the peak amplifier 12 is made greater than the saturation power of the peak amplifier 14. As a result, the overall gain is greater than that of the first embodiment near P2, where the probability of a modulated wave is high. Therefore, the gain of the modulated wave can be improved more than that of the first embodiment, and the characteristics can be further improved.

From the viewpoint of improving the gain of the modulated wave, the saturation power Ps2 (indicated in W) of the peak amplifier 12 may be set to 1.2 times or more, 1.5 times or more, or 2 times or more, the saturation power Ps3 (indicated in W) of the peak amplifier 14. If the saturation power Ps3 of the peak amplifier 14 is too small, the gain will decrease when the input power Pin is large. From this viewpoint, the saturation power Ps2 may be set to 10 times or less, or 5 times or less the saturation power Ps3. The saturation power ratio Ps2/Ps3 may be set to 0.5 times or more and 2 times or less, or 0.8 times or more and 1.25 times or less, the distribution ratio A2/A3 of the divider 16.

The above explanation takes a 3-way Doherty amplifier circuit as an example, but in the case of an N-way Doherty amplifier circuit, N−1 peak amplifiers are sufficient. In FIG. 4, it has been described that the main amplifier 10 and the peak amplifiers 12 and 14 have the same saturation power when the same gate bias voltage and drain bias voltage are supplied to the main amplifier 10 and the peak amplifiers 12 and 14. However, the saturation power of the main amplifier 10 and the peak amplifiers 12 and 14 may be different.

The embodiments disclosed here should be considered illustrative in all respects and not restrictive. The present disclosure is not limited to the specific embodiments described above, but various variations and changes are possible within the scope of the gist of the present disclosure as described in the claims.

1. A Doherty amplifier circuit comprising:
a divider configured to divide an input signal into a first signal, a second signal and a third signal and makes power of the second signal larger than that of the third signal;
a main amplifier configured to amplify the first signal and output the first signal after amplifying as a fourth signal;
a first peak amplifier configured to amplify the second signal and output the second signal after amplifying as a fifth signal;
a second peak amplifier configured to amplify the third signal and output the third signal after amplifying as a sixth signal; and
a combiner configured to combine the fourth signal, the fifth signal and the sixth signal and output a combined signal of the fourth signal, the fifth signal and the sixth signal as an output signal to an output terminal,
wherein an input power of the input signal for turning on the first peak amplifier is smaller than the input power for turning on the second peak amplifier.

2. The Doherty amplifier circuit as claimed in claim 1,
wherein when the main amplifier and the first peak amplifier are operating and the second peak amplifier is not operating, a first distance between a first position on a Smith chart of impedance at a center frequency of an operating band in a case of seeing the combiner from the first peak amplifier and a second position on the Smith chart of the impedance at the center frequency in a case of seeing the combiner from the first peak amplifier at which the gain of the first peak amplifier is maximum is smaller than a second distance between a position on the Smith chart of impedance at the center frequency in a case of seeing the combiner from the main amplifier and a position on the Smith chart of the impedance at the center frequency in a case of seeing the combiner from the main amplifier at which the gain of the main amplifier is maximum.

3. The Doherty amplifier circuit as claimed in claim 2,
wherein the first position on the Smith chart is located within a circle having the second position as center thereof and a diameter equal to a distance between the second position and a third position on the Smith chart of the impedance at the center frequency in a case of seeing the combiner from the first peak amplifier, at which the efficiency of the first peak amplifier is maximized.

4. The Doherty amplifier circuit as claimed in claim 2,
wherein when the main amplifier, the first peak amplifier and the second peak amplifier are operating, a third distance between a fourth position on the Smith chart of the impedance at the center frequency in a case of seeing the combiner from the first peak amplifier and the second position is less than or equal to the first distance.

5. The Doherty amplifier circuit as claimed in claim 1,
wherein when a same bias voltage is supplied to the first peak amplifier and the second peak amplifier, a saturation electrical power of the first peak amplifier is larger than that of the second peak amplifier.

6. The Doherty amplifier circuit as claimed in claim 1,
wherein when a same bias voltage is supplied to the first peak amplifier and the second peak amplifier, a saturation electrical power of the first peak amplifier is equal to that of the second peak amplifier.
